(19) United States
(12) Patent Application Publication
(10) Pub. No.: US 2026/0293501 A1
(43) Pub. Date: Sep. 24, 2026

(54) DISPLAY DEVICE AND ELECTRONIC DEVICE

(71) Applicant: Samsung Display Co., Ltd., Yongin-si (KR)

(72) Inventors: JUNHYUK WOO, Yongin-si (KR); RAE-YOUNG KIM, Yongin-si (KR); REEHYANG KIM, Yongin-si (KR); SOODONG KIM, Yongin-si (KR); JONGMIN OK, Yongin-si (KR); JEWON YOO, Yongin-si (KR); JONGBEOM HONG, Yongin-si (KR)

(21) Appl. No.: 19/385,470

(22) Filed: Nov. 11, 2025

(30) Foreign Application Priority Data
Mar. 18, 2025 (KR) 10-2025-0034904

(51) Int. Cl. H10K 59/80; H10K 59/122; H10K 59/40

(52) U.S. Cl. CPC H10K 59/879; H10K 59/122; H10K 59/40; H10K 59/8792

(57) ABSTRACT

A display device includes: a display panel; a first insulating layer on the display panel and having a first refractive index; and a second insulating layer on the first insulating layer and having a second refractive index different from the first refractive index, the display panel including: a pixel definition layer through which a light emitting opening comprising a first side extending in a first direction is defined; and a light emitting element in the light emitting opening, wherein an opening comprising a second side extending in the first direction is defined through the first insulating layer to overlap with the light emitting opening, and a distance between the first side and the second side is greater than or equal to 4 micrometers and smaller than or equal to 6 micrometers in a plan view.

### CROSS-REFERENCE TO RELATED APPLICATION

The present application claims priority to and the benefit of Korean Patent Application No. 10-2025-0034904, filed on Mar. 18, 2025, in the Korean Intellectual Property Office, the entire disclosure of which is incorporated herein by reference.

### BACKGROUND

### 1. Field

Aspects of some embodiments of the present disclosure relate to a display device and an electronic device.

### 2. Description of the Related Art

Various electronic devices, such as televisions, mobile phones, tablet computers, navigation systems, and gaming consoles, may include a display device to display images. The display device may include a light emitting element, such as an organic light emitting diode, which emits light. The light generated from the light emitting element is emitted not only in a forward direction of the electronic device but also in a lateral direction. The light emission efficiency of the display device varies depending on the direction in which the light is emitted, and thus, technological developments to improve the light emission efficiency of the display device may be desirable.

The above information disclosed in this Background section is only for enhancement of understanding of the background and therefore the information discussed in this Background section does not necessarily constitute prior art.

### SUMMARY

Aspects of some embodiments of the present disclosure relate to a display device and an electronic device. For example, aspects of some embodiments of the present disclosure relate to a display device with relatively improved light emission efficiency and an electronic device.

Aspects of some embodiments of the present disclosure include a display device with relatively improved light emission efficiency and side viewing angle and an electronic device.

Aspects of some embodiments of the present disclosure include a display device including a display panel, a first insulating layer on the display panel and having a first refractive index, and a second insulating layer on the first insulating layer and having a second refractive index different from the first refractive index. The display panel includes a pixel definition layer through which a light emitting opening including a first side extending in a first direction is defined and a light emitting element in the light emitting opening. An opening including a second side extending in the first direction is defined through the first insulating layer to overlap with the light emitting opening. According to some embodiments, a distance between the first side and the second side is greater than or equal to 4 micrometers and smaller than or equal to 6 micrometers in a plan view.

Aspects of some embodiments of the present disclosure include a display device including a display panel, an organic pattern on the display panel and having a first refractive index, and an insulating layer on the organic pattern and having a second refractive index different from the first refractive index. According to some embodiments, the display panel includes a pixel definition layer through which a light emitting opening including a first side extending in a first direction is defined and a light emitting element in the light emitting opening. According to some embodiments, the organic pattern includes a second side extending in the first direction and defining the organic pattern in a plan view, and a distance between the first side and the second side is greater than or equal to 4 micrometers and smaller than or equal to 6 micrometers in the plan view.

1 Aspects of some embodiments of the present disclosure include an electronic device including a display panel displaying an image, a processor providing image data to the display panel, a first insulating layer on the display panel and having a first refractive index, a second insulating layer on the first insulating layer and having a second refractive index different from the first refractive index, and a window on the second insulating layer. According to some embodiments, the display panel includes a pixel definition layer through which a light emitting opening including a first side extending in a first direction is defined and a light emitting element in the light emitting opening. According to some embodiments, an opening including a second side extending in the first direction is defined through the first insulating layer to overlap with the light emitting opening. According to some embodiments, a distance between the first side and the second side is greater than or equal to 4 micrometers and smaller than or equal to 6 micrometers in a plan view.

According to some embodiments, the difference in width between the light emitting opening through which the light emitting element is exposed and the opening of the first insulating layer to a selected value is adjusted, and a thickness of the first insulating layer to a selected value is adjusted. Thus, the light emission efficiency of the display device may be relatively improved.

### BRIEF DESCRIPTION OF THE DRAWINGS

FIG. 1 is a block diagram of an electronic device according to some embodiments of the present disclosure;

FIG. 2 is a schematic view of various electronic devices according to embodiments of the present disclosure;

FIG. 3 is a perspective view of an electronic device according to some embodiments of the present disclosure;

FIG. 4 is an exploded perspective view of an electronic device according to some embodiments of the present disclosure;

1 FIGS. 5A and 5B are cross-sectional views of display devices taken along a line I-I′ of FIG. 4 according to some embodiments of the present disclosure;

FIG. 6 is a plan view of a display panel according to some embodiments of the present disclosure;

FIG. 7 is a plan view of an input sensing layer according to some embodiments of the present disclosure;

FIG. 8 is an enlarged plan view of an active area of a display panel according to some embodiments of the present disclosure;

FIG. 9 is a cross-sectional view of a display device taken along a line II-II′ of FIG. 8 according to some embodiments of the present disclosure;

FIG. 10 is a cross-sectional view of a portion of a display device according to some embodiments of the present disclosure;

FIG. 11 is a cross-sectional view of a display device taken along a line III-III′ of FIG. 8 according to some embodiments of the present disclosure;

FIG. 12 is a diagram representing graphs of a side luminance and a front light emission efficiency of a display device according to some embodiments of the present disclosure; and

FIG. 13 is a cross-sectional view of a portion of a display device according to some embodiments of the present disclosure.

### DETAILED DESCRIPTION

The present disclosure may be variously modified and realized in many different forms, and thus aspects of some embodiments will be illustrated in the drawings and described in detail hereinbelow. However, embodiments according to the present disclosure should not be limited to the specific disclosed forms, and be construed to include all modifications, equivalents, or replacements included in the spirit and scope of the present disclosure.

In the present disclosure, it will be understood that when an element (or area, layer, or portion) is referred to as being “on”, “connected to” or “coupled to” another element or layer, it can be directly on, connected or coupled to the other element or layer or intervening elements or layers may be present.

Like numerals refer to like elements throughout. In the drawings, the thickness, ratio, and dimension of components are exaggerated for effective description of the technical content. As used herein, the term “and/or” may include any and all combinations of one or more of the associated listed items.

It will be understood that, although the terms first, second, etc. may be used herein to describe various elements, these elements should not be limited by these terms. These terms are only used to distinguish one element from another element. Thus, a first element discussed below could be termed a second element without departing from the teachings of the present disclosure. As used herein, the singular forms, “a”, “an” and “the” are intended to include the plural forms as well, unless the context clearly indicates otherwise.

Spatially relative terms, such as “below”, “lower”, “above”, “upper” and the like, may be used herein for ease of description to describe one element or feature's relationship to another elements or features as shown in the figures.

It will be further understood that the terms “include” and/or “including”, when used in this specification, specify the presence of stated features, integers, steps, operations, elements, and/or components, but do not preclude the presence or addition of one or more other features, integers, steps, operations, elements, components, and/or groups thereof.

In the present disclosure, when an element is referred to as being “directly connected” to another element, there are no intervening elements present between a layer, film region, or substrate and another layer, film, region, or substrate. For example, the term “directly connected” may mean that two layers or two members are arranged without employing additional adhesive therebetween.

Unless otherwise defined, all terms including technical and scientific terms used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, a display device according to some embodiments of the present disclosure will be described with reference to accompanying drawings.

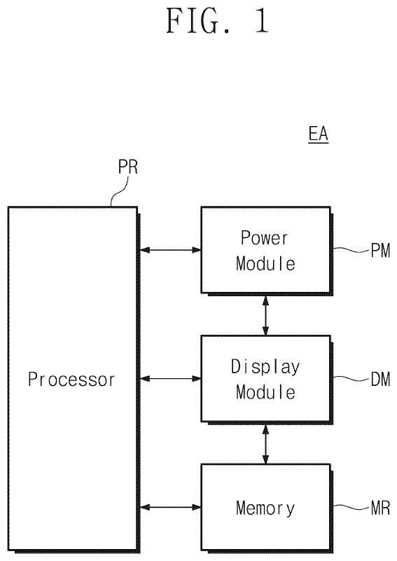

FIG. 1 is a block diagram of an electronic device according to some embodiments of the present disclosure.

Referring to FIG. 1, the electronic device EA may include a display module DM, a processor PR, a memory MR, and a power module PM.

The processor PR may include at least one of a central processing unit (CPU), an application processor (AP), a graphics processing unit (GPU), a communication processor (CP), an image signal processor (ISP), or a controller.

The memory MR may store data information required for the operation of the processor PR or the display module DM. When the processor PR executes an application stored in the memory MR, an image data signal and/or an input control signal may be transmitted to the display module DM, and the display module DM may process the received signals to output image information through a display screen. The display module DM may include a display panel that displays images.

The power module PM may include a power supply module, such as a power adapter or a battery device, and a power conversion module that converts power supplied by the power supply module to generate power required for the operation of the electronic device EA.

At least one of components of the electronic device EA may be included in the display module and the display device including the display module according to following embodiments. In addition, among individual modules that are functionally included within a single module, some may be included in the display device while others may be provided separately from the display device. As an example, the display device may include the display module DM, and the processor PR, the memory MR, and the power module PM may be provided as separate devices within the electronic device EA without being included in the display device.

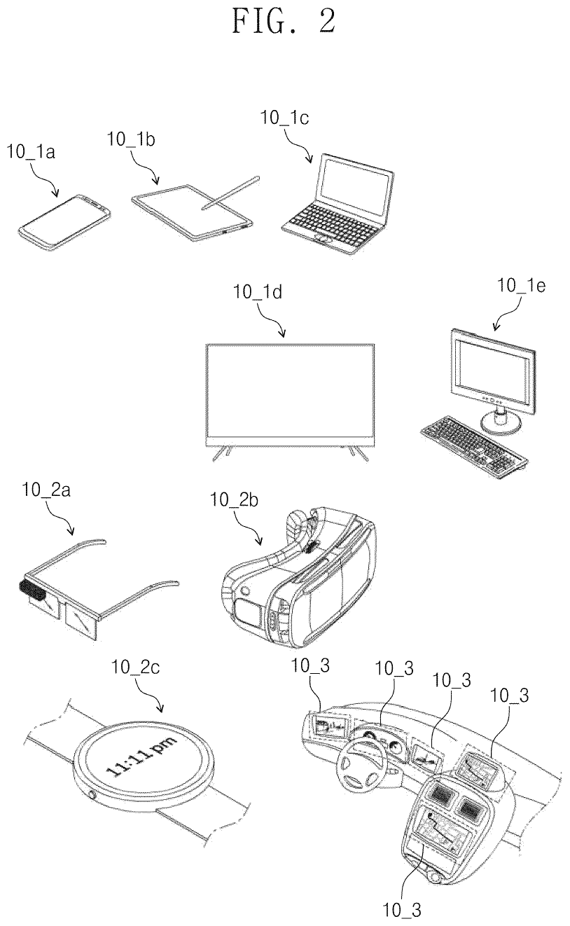

FIG. 2 is a schematic view of various electronic devices according to embodiments of the present disclosure.

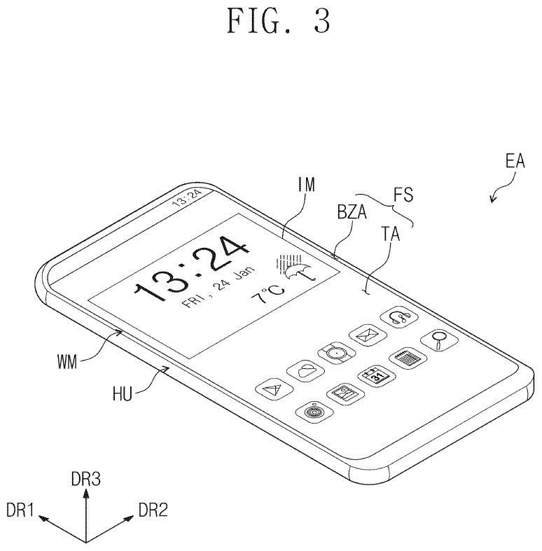

Referring to FIG. 2, various electronic devices to which the display module according to some embodiments is applied may include not only an electronic device to display images, such as a smartphone 10_1a, a tablet PC 10_1b, a laptop computer 10_1c, a television 10_1d, a desktop monitor 10_1e, etc., but also a wearable electronic device, such as a smart glasses 10_2a, a head-mounted display 10_2b, a smartwatch 10_2c, etc., and an in-vehicle electronic device 10_3, such as an instrument panel, a center fascia, a dashboard-mounted center information display (CID), or a room mirror display. The electronic device EA according to the present disclosure may be a mobile phone as illustrated in FIG. 3, however, it should not be limited thereto or thereby.

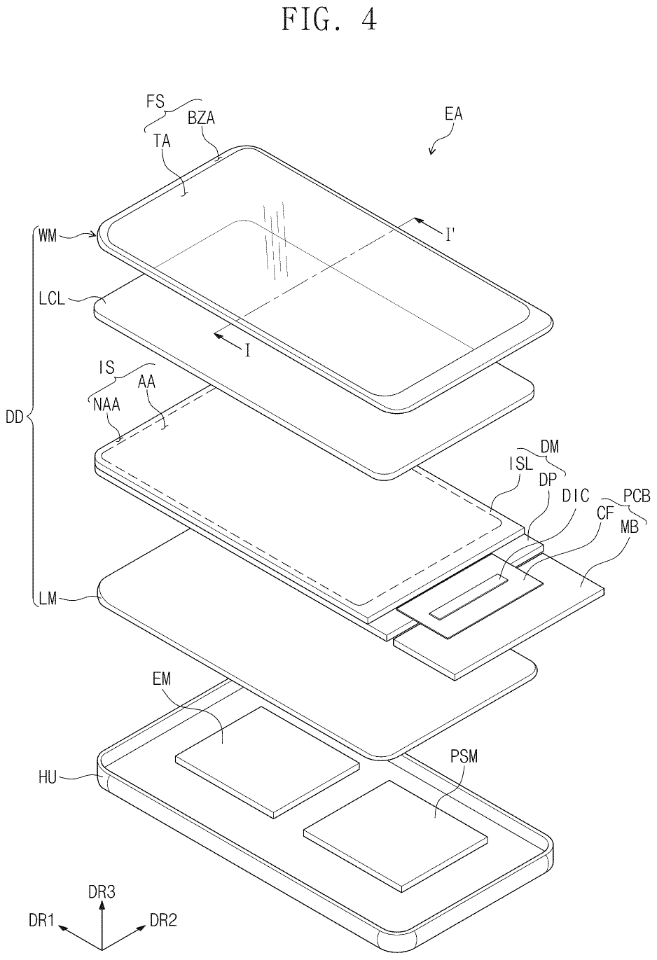

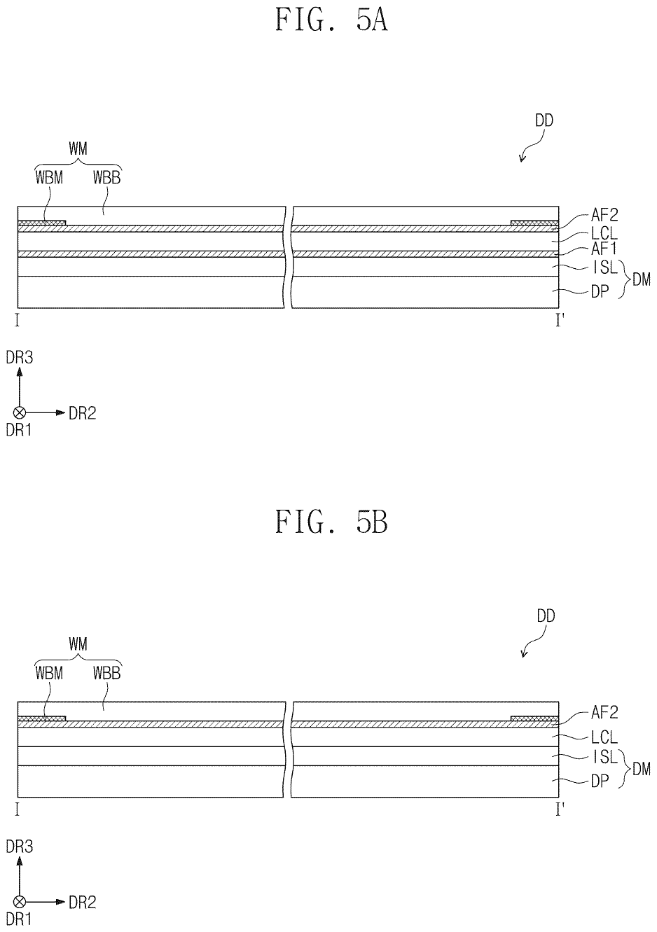

FIG. 3 is a perspective view of the electronic device according to some embodiments of the present disclosure. FIG. 4 is an exploded perspective view of the electronic device according to some embodiments of the present disclosure.

The electronic device EA may be activated in response to electrical signals. The electronic device EA may be applied to various embodiments. For example, the electronic device EA may be applied to electronic devices, such as a mobile phone, a smart watch, a tablet computer, a notebook computer, a computer, or a smart television. The display device according to the present disclosure should not be limited to the above examples and may be applied to other electronic devices as long as they do not depart from the concept of the present disclosure. The mobile phone is shown as an example of the electronic device EA according to the present disclosure.

The electronic device EA may display an image IM toward a third direction DR3 through a display surface FS that is substantially parallel to each of a first direction DR1 and a second direction DR2. The display surface FS through which the image IM is displayed may correspond to a front surface of the electronic device EA. The image IM may include a still image as well as a video. FIG. 3 shows a clock widget and application icons as representative examples of the image IM

According to some embodiments, front (or upper) and rear (or lower) surfaces of each member may be defined with respect to a direction to which the image IM is displayed. The front and rear surfaces may be opposite to each other in the third direction DR3, and a normal line direction of each of the front and rear surfaces may be substantially parallel to the third direction DR3. A separation distance in the third direction DR3 between the front surface and the rear surface may correspond to a thickness in the third direction DR3 of the display device DD. In the present disclosure, the expressions “when viewed in a plane” or “in a plan view” may refer to the state of being viewed in the third direction DR3. Directions indicated by the first, second, and third directions DR1, DR2, and DR3 are relative to each other, and thus, the directions indicated by the first, second, and third directions DR1, DR2, and DR3 may be changed to other directions.

The electronic device EA may sense an external input applied from the outside. The external input may include inputs of various forms provided from the outside of the electronic device EA. As an example, the external input may include external inputs applied when in proximity to or approaching close to the electronic device EA at a distance (e.g., a set or predetermined distance) (e.g., a hovering input) as well as a touch input by a user's body, e.g., a hand of a user. In addition, the external input may include various forms, such as force, pressure, temperature, or light.

The electronic device EA may include a window WM and a housing HU. The window WM may be coupled to the housing HU to provide an exterior of the electronic device EA.

The window WM may include a transmission area TA and a bezel area BZA. The front surface of the electronic device EA may correspond to the transmission area TA and the bezel area BZA of the window WM.

The image IM may be displayed through the transmission area TA. The transmission area TA may be optically transparent. The user may view the image IM through the transmission area TA.

According to some embodiments, the transmission area TA may have a quadrangular shape with rounded vertices. However, this is merely an example, and the transmission area TA may have a variety of shapes and should not be particularly limited.

The bezel area BZA may have a light transmittance that is relatively lower than that of the transmission area TA. The bezel area BZA may be an area defined by printing a material with a selected color.

The bezel area BZA may be defined adjacent to the transmission area TA. The bezel area BZA may surround the transmission area TA. Accordingly, the shape of the transmission area TA may be defined by the bezel area BZA. However, this is merely an example, and the bezel area BZA may be located adjacent to only one side of the transmission area TA or may be omitted.

Referring to FIGS. 3 and 4, the electronic device EA may include the display device DD, an electronic module EM, a power source module PSM, and the housing HU. FIG. 4 schematically shows the electronic device EA, and the electronic device EA may further include a mechanical structure, e.g., a hinge structure, to control the operation, e.g., a folding or rolling operation, of the display device DD.

The display device DD may include the window WM, a light control layer LCL, a display module DM, a lower member LM, a driving chip DIC, and a printed circuit board PCB. The display module DM may include a display panel DP and an input sensing layer ISL.

The window WM may be located on the display module DM. The window WM may protect the display module DM. The window WM may include an optically transparent material. As an example, the window WM may include a glass, sapphire, or plastic material. Images provided from the display module DM may be provided to the user through the window WM.

The window WM may have a single-layer or multi-layer structure. As an example, the window WM may include a plurality of plastic films attached to each other or a glass substrate and a plastic film attached to the glass substrate.

The light control layer LCL may control a path of light generated from the display panel DP. The light control layer LCL may concentrate the light provided from the display panel DP or may further spread the light generated from specific areas of the display panel DP. Detailed descriptions of the light control layer LCL will be provided later.

The display module DM may include a front surface IS including an active area AA and a peripheral area NAA. The active area AA may be activated in response to electrical signals. As an example, the image IM may be displayed through the active area AA, and the external input may be sensed in the active area AA.

The transmission area TA may overlap at least a portion of the active area AA. Accordingly, the user may view the image IM or may provide the external input through the transmission area TA. However, this is merely an example. An area where the image IM is displayed and an area where the external input is sensed may be separated from each other in the active area AA, and they should not be particularly limited.

The peripheral area NAA may be covered by the bezel area BZA. The peripheral area NAA may be defined adjacent to the active area AA. For example, the peripheral area NAA may surround the active area AA. A driving circuit or a driving line to drive the active area AA may be arranged in the peripheral area NAA.

The display panel DP according to some embodiments may be a liquid crystal display panel or a light-emitting type display panel, however, it should not be particularly limited. For instance, the display panel DP may be an organic light emitting display panel or a quantum dot light emitting display panel. A light emitting layer of the organic light emitting display panel may include an organic light emitting material. A light emitting layer of the quantum dot light emitting display panel may include a quantum dot or a quantum rod.

The display panel DP may be flexible. The term “flexible” used herein refers to the property of being able to be bent from a structure that is completely bent to a structure that is partially bent. For example, the display panel DP may be a curved display panel or a foldable display panel DP. However, the display panel DP should not be limited thereto or thereby, and the display panel DP may be rigid.

The input sensing layer ISL may be located on the display panel DP. As shown in FIG. 4, the input sensing layer ISL may be located directly on the display panel DP. That is, the input sensing layer ISL may be formed on the display panel DP through a continuous process, and an adhesive film may not be located between the input sensing layer ISL and the display panel DP. However, embodiments according to the present disclosure are not limited thereto or thereby, and an adhesive film may be located between the input sensing layer ISL and the display panel DP. The input sensing layer ISL may be manufactured through a separate process from the display panel DP and then fixed to an upper surface of the display panel DP by an adhesive film.

The input sensing layer ISL may sense the external input applied from the outside. As described above, the input sensing layer ISL may sense the external input provided to the window WM.

The printed circuit board PCB may be located at one side of the display panel DP. The printed circuit board PCB may include a connection circuit board CF and a main circuit board MB.

The connection circuit board CF may connect the display panel DP and the main circuit board MB. The connection circuit board CF may be electrically connected to the display panel DP at one side of the connection circuit board CF, which is adjacent to the display panel DP. The connection circuit board CF may be electrically connected to the main circuit board MB at the other side of the connection circuit board CF, which is adjacent to the main circuit board MB.

According to some embodiments, one connection circuit board CF connecting the display panel DP and the main circuit board MB is shown, but embodiments according to the present disclosure are not limited thereto or thereby. According to some embodiments, the connection circuit board CF may be provided in plural, and the connection circuit boards CF may connect the display panel DP and the main circuit board MB.

The connection circuit board CF may be a flexible printed circuit board. The connection circuit board CF may apply electrical signals to the display panel DP to drive the display panel DP. The electrical signals may be generated by the connection circuit board CF or the main circuit board MB.

The driving chip DIC may be mounted on the connection circuit board CF. The driving chip DIC may be mounted on the flexible printed circuit board to form a chip-on-film (COF). The driving chip DIC may include driving elements to drive pixels of the display panel DP. The driving chip DIC may include a driving circuit, and the driving circuit may be implemented as an integrated circuit. The driving circuit may include a driving controller, a data driver, a voltage generator, and the like.

The main circuit board MB may include a main controller. The main circuit board MB may include signal lines to transmit control signals and image signals from the main controller to the connection circuit board CF and the display panel DP.

According to some embodiments, the printed circuit board PCB may further include an input circuit board that is electrically connected to the input sensing layer ISL. The input circuit board may connect the input sensing layer ISL and the main circuit board MB. According to some embodiments, the input circuit board may be provided as a flexible circuit film and may connect the input sensing layer ISL and the main circuit board MB. The input circuit board may apply electrical signals to the input sensing layer ISL to drive the input sensing layer ISL. The electrical signals may be generated by the input circuit board or the main circuit board MB.

Each of the connection circuit board CF and the input circuit board may be connected to one main circuit board MB. One of the connection circuit board CF and the input circuit board may not be connected to the main circuit board MB, but it should not be particularly limited.

The lower member LM may be located under the display panel DP. The lower member LM may include a protective film to protect the display panel DP, a support member to support the display panel DP, a digitizer, and the like.

The electronic module EM and the power source module PSM may be located under the display module DM. The electronic module EM and the power source module PSM may be electrically connected to each other through a separate circuit board.

The power source module PSM may supply power required for the operation of the electronic device EA. As an example, the power source module PSM may include a conventional battery module.

The electronic module EM may include a control module, a wireless communication module, an image input module, an audio input module, an audio output module, a memory, and an external interface module. The electronic module EM may include a main circuit board, and the modules may be mounted on the main circuit board or may be electrically connected to the main circuit board via the flexible printed circuit board. The electronic module EM may be electrically connected to the power source module PSM.

According to some embodiments, the electronic device EA may further include an electro-optical module. The electro-optical module may be an electronic component configured to emit or receive an optical signal. The electro-optical module may include a camera module and/or a proximity sensor. The camera module may capture external images through a certain region of the display panel DP.

The housing HU shown in FIG. 4 may be coupled with the display device DD, particularly with the window WM, to accommodate the modules. Although the housing HU is shown as having an integral shape, it should not be limited thereto. The housing HU may include a plurality of parts coupled to each other, such as a side frame portion and a bottom portion. The housing HU may protect the display module DM, which is accommodated in an inner space, from external impacts and may prevent or reduce contaminants or foreign substances or moisture entering the display module DM.

FIGS. 5A and 5B are cross-sectional views of display devices taken along a line I-I′ of FIG. 4 according to embodiments of the present disclosure. FIGS. 5A and 5B schematically illustrate various embodiments based on the stacked structure of components of the display device DD. The descriptions previously provided may also be applied to the components of the display device DD shown in FIGS. 5A and 5B.

Referring to FIGS. 5A and 5B, the window WM may include a base substrate WBB and a bezel pattern WBM. The base substrate WBB may include an optically transparent insulating material. The base substrate WBB may include at least one of a glass substrate or a synthetic resin film. The base substrate WBB may have a single-layer structure or a multi-layer structure. Functional layers, such as an anti-fingerprint layer, a phase-controlling optical layer, a hard coating layer, etc., may be located on the base substrate WBB.

The bezel pattern WBM may be a colored layer formed on one surface of the base substrate WBB. The bezel pattern WBM may have a single-layer or multi-layer structure. The bezel pattern WBM having the multi-layer structure may include a chromatic color layer and a light blocking layer having an achromatic color, e.g., a black color. The bezel pattern WBM may be formed on the base substrate WBB through a depositing, printing, or coating process. An area in which the bezel pattern WBM is arranged may correspond to the bezel area BZA of the window WM.

Referring to FIG. 5A, the window WM and the light control layer LCL may be respectively coupled to components located thereunder by adhesive layers AF2 and AF1. The light control layer LCL may be attached to the display module DM by a first adhesive layer AF1. In detail, the light control layer LCL may be fixed to an upper surface of the input sensing layer ISL by the first adhesive layer AF1. The window WM may be attached to the light control layer LCL by a second adhesive layer AF2.

Each of the first and second adhesive layers AF1 and AF2 may include a transparent adhesive, such as an optically clear adhesive (OCA) film, an optically clear resin (OCR), or a pressure sensitive adhesive (PSA) film. However, the types of the first and second adhesive layers AF1 and AF2 are not limited to those described above.

Referring to FIG. 5B, the light control layer LCL may be located directly on the display module DM. In detail, the light control layer LCL may be formed on the input sensing layer ISL through a continuous process. As an example, the light control layer LCL may be formed by coating or printing a composition of a color filter on a base surface provided by the input sensing layer ISL and patterning the coated or printed composition. Because the light control layer LCL is located directly on the display module DM, the first adhesive layer AF1 of FIG. 5A may be omitted.

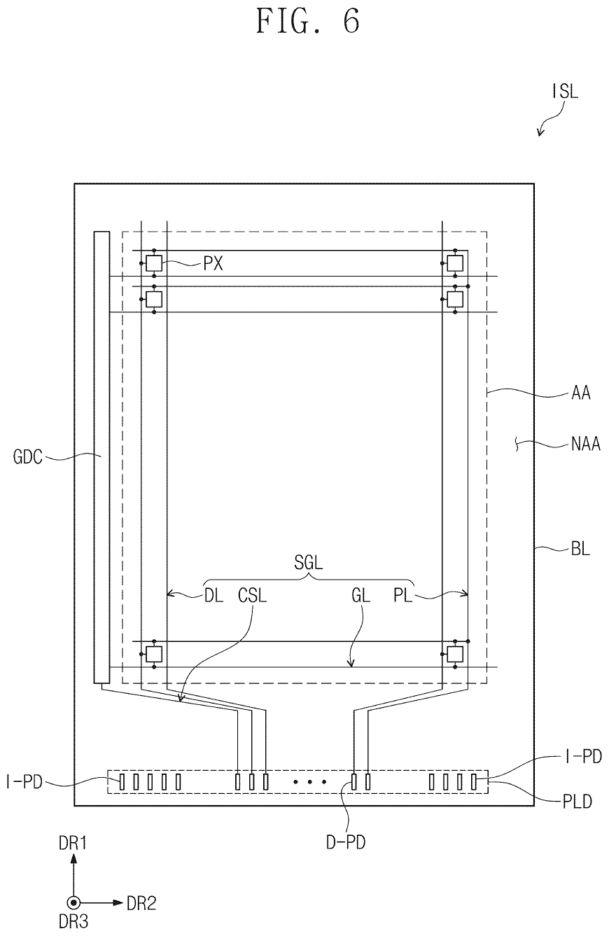

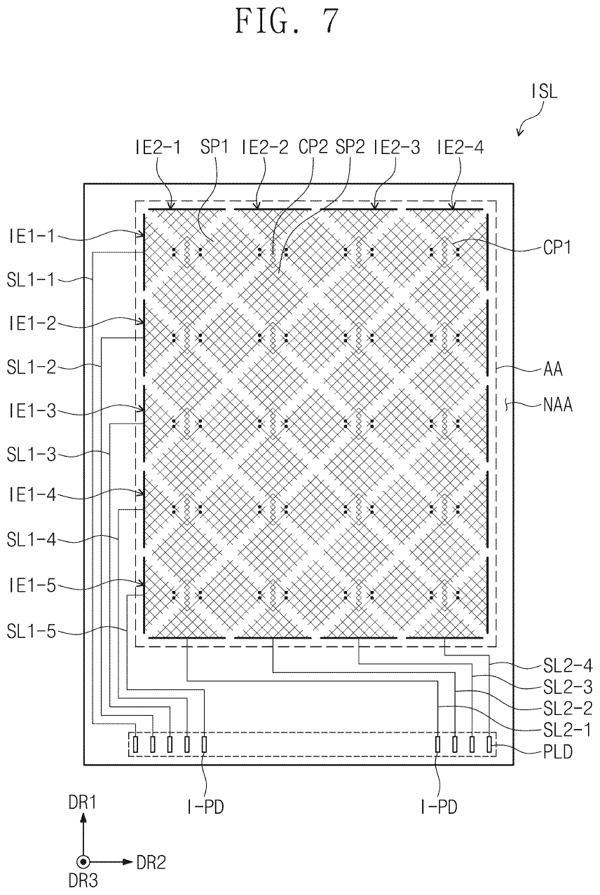

FIG. 6 is a plan view of the display panel according to some embodiments of the present disclosure, and FIG. 7 is a plan view of the input sensing layer according to some embodiments of the present disclosure.

Referring to FIG. 6, the display panel DP may include a base layer BL including the active area AA and the peripheral area NAA. The display panel DP may include the pixels PX arranged in the active area AA and signal lines SGL electrically connected to the pixels PX. The display panel DP may include a driving circuit GDC and a pad part PLD, which are arranged in the peripheral area NAA.

Each of the pixels PX may include a light emitting element and a pixel driving circuit connected to the light emitting element. The signal lines SGL may include gate lines GL, data lines DL, a power line PL, and a control signal line CSL. Each of the gate lines GL may be connected to a corresponding pixel PX among the pixels PX, and each of the data lines DL may be connected to a corresponding pixel PX among the pixels PX. The power line PL may be electrically connected to the pixels PX. The control signal line CSL may be connected to the driving circuit GDC and may provide control signals to the driving circuit GDC.

The driving circuit GDC may include a gate driving circuit. The gate driving circuit may generate gate signals and may sequentially output the generated gate signals to the gate lines GL. The gate driving circuit may further output another control signal to the pixel driving circuit.

The pad part PLD may be a portion to which the connection circuit board CF of FIG. 4 is connected. The pad part PLD may include pixel pads D-PD and input pads I-PD. The pixel pads D-PD may be pads to connect the connection circuit board CF to the display panel DP. The input pads I-PD may be pads to connect the connection circuit board CF to the input sensing layer ISL.

Each of the pixel pads D-PD may be connected to a corresponding signal line of the signal lines SGL. Each of the pixel pads D-PD may be connected to a corresponding pixel PX through the signal lines SGL. In addition, one of the pixel pads D-PD may be connected to the driving circuit GDC.

Referring to FIG. 7, the input sensing layer ISL according to some embodiments may include a plurality of sensing electrodes and a plurality of signal lines. The input sensing layer ISL may include first sensing electrodes IE1-1 to IE1-5 and second sensing electrodes IE2-1 to IE2-4. The input sensing layer ISL may further include first signal lines SL1-1 to SL1-5 connected to the first sensing electrodes IE1-1 to IE1-5 and second signal lines SL2-1 to SL2-4 connected to the second sensing electrodes IE2-1 to IE2-4.

The first sensing electrodes IE1-1 to IE1-5 and the second sensing electrodes IE2-1 to IE2-4 may intersect each other. The first sensing electrodes IE1-1 to IE1-5 may extend in the second direction DR2 and may be arranged in the first direction DR1. The second sensing electrodes IE2-1 to IE2-4 may extend in the first direction DR1 and may be arranged in the second direction DR2. The first sensing electrodes IE1-1 to IE1-5 and the second sensing electrodes IE2-1 to IE2-4 may be electrically insulated from each other.

The first signal lines SL1-1 to SL1-5 and the second signal lines SL2-1 to SL2-4 may be arranged in the peripheral area NAA. Each of the first signal lines SL1- to SL1-5 and the second signal lines SL2-1 to SL2-4 may be connected to the input pads I-PD arranged in the peripheral area NAA.

Each of the first signal lines SL1-1 to SL1-5 may be connected to one end of a corresponding first sensing electrode of the first sensing electrodes IE1-1 to IE1-5. Some of the first signal lines SL1-1 to SL1-5 may be connected to one end of the first sensing electrodes, while the remaining signal lines of the first signal lines SL1-1 to SL1-5 may be connected to the other end of the first sensing electrodes, but embodiments according to the present disclosure are not limited thereto.

Each of the second signal lines SL2-1 to SL2-4 may be connected to one end of a corresponding second sensing electrode of the second sensing electrodes IE2-1 to IE2-4. The input sensing layer ISL may further include signal lines connected to the other ends of the second sensing electrodes IE2-1 to IE2-4, but embodiments according to the present disclosure are not limited thereto.

Each of the first sensing electrodes IE1-1 to IE1-5 may include first sensor parts SP1 and first connection parts CP1, which are arranged in the active area AA. In one first sensing electrode, the first sensor parts SP1 may be arranged in the second direction DR2. Each of the first connection parts CP1 may connect the first sensor parts SP1 adjacent to each other in the second direction DR2.

Each of the second sensing electrodes IE2-1 to IE2-4 may include second sensor parts SP2 and second connection parts CP2, which are arranged in the active area AA. In one second sensing electrode, the second sensor parts SP2 may be arranged in the first direction DR1. Each of the second connection parts CP2 may connect the second sensor parts SP2 adjacent to each other in the first direction DR1.

The first sensor parts SP1 of the first sensing electrodes IE1-1 to IE1-5, the second sensor parts SP2 of the second sensing electrodes IE2-1 to IE2-4, and the second connection parts CP2 of the second sensing electrodes IE2-1 to IE2-4 may be formed at the same layer. In one first sensing electrode, the first sensor parts SP1 may be spaced apart from each other, and the second sensing electrodes IE2-1 to IE2-4 located at the same layer as the first sensor parts SP1 may be arranged between the first sensor parts SP1. The first connection part CP1 may be formed at a layer different from the first sensor parts SP1 and may overlap with the first sensor parts SP1 when viewed in a plane (or in a plan view). The first connection part CP1 may be electrically connected to the first sensor parts SP1 that overlap with the first connection part CP1 and may electrically connect the first sensor parts SP1 adjacent to each other.

Each of the first sensing electrodes IE1-1 to IE1-5 and the second sensing electrodes IE2-1 to IE2-4 may have a mesh shape. Because the first sensing electrodes IE1-1 to IE1-5 and the second sensing electrodes IE2-1 to IE2-4 have the mesh shape, a parasitic capacitance between these sensing electrodes and electrodes of the display panel DP (refer to FIG. 6) may be relatively reduced. In addition, the first sensing electrodes IE1-1 to IE1-5 and the second sensing electrodes IE2-1 to IE2-4 may not overlap with the light emitting areas of the display panel DP (refer to FIG. 6), and thus, visibility of the sensing electrodes from outside the display device DD may be prevented or reduced.

Each of the first sensing electrodes IE1-1 to IE1-5 and the second sensing electrodes IE2-1 to IE2-4 may include materials such as silver, aluminum, copper, chromium, nickel, titanium, or the like, which may be processed at low temperatures. Accordingly, even when the input sensing layer ISL is formed on the display panel DP through a continuous process, the low temperature processing prevents or reduces damage to the light emitting elements of the display panel DP. However, the materials of the first sensing electrodes IE1-1 to IE1-5 and the second sensing electrodes IE2-1 to IE2-4 should not be limited thereto or thereby.

FIG. 7 illustrates the first sensing electrodes IE1-1 to IE1-5 and the second sensing electrodes IE2-1 to IE2-4 as a representative example, but the shape of the sensing electrodes should not be limited thereto or thereby. According to some embodiments, the first sensing electrodes IE1-1 to IE1-5 and the second sensing electrodes IE2-1 to IE2-4 may have a shape, e.g., a bar shape, in which the sensor part and the connection part are not distinguished. In addition, FIG. 7 illustrates the first sensor parts SP1 and the second sensor parts SP2 having a rhombus shape, however, the shape of the first sensor parts SP1 and the second sensor parts SP2 should not be limited thereto or thereby and may have various polygonal shapes.

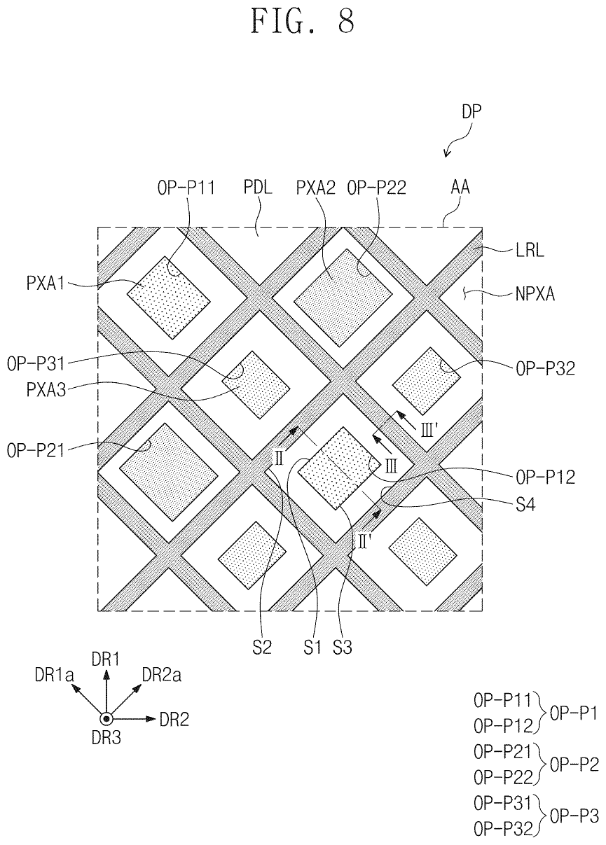

FIG. 8 is an enlarged plan view of the active area of the display panel according to some embodiments of the present disclosure.

Referring to FIG. 8, the active area AA of the display panel DP may include a plurality of light emitting areas PXA1, PXA2, and PXA3 and a non-light-emitting area NPXA. The light emitting areas PXA1, PXA2, and PXA3 may be areas from which the light exits. The non-light-emitting area NPXA may surround the light emitting areas PXA1, PXA2, and PXA3 and may define a boundary between the light emitting areas PXA1, PXA2, and PXA3.

The display panel DP may include a pixel definition layer PDL through which a plurality of light emitting openings is defined and the light emitting elements arranged to correspond to the light emitting openings. Areas of the light emitting openings may correspond to the light emitting areas PXA1, PXA2, and PXA3, respectively. An area in which the pixel definition layer PDL is located may correspond to the non-light-emitting area NPXA and may prevent or reduce a color mixture of the lights exiting through the light emitting areas PXA1, PXA2, and PXA3.

A first crossing direction DR1a and a second crossing direction DR2a, which intersect with the first direction DR1 and the second direction DR2, respectively, may be defined. An angle between the first crossing direction DR1a and the first direction DR1 and an angle between the second crossing direction DR2a and the second direction DR2 may be acute angles. The first crossing direction DR1a and the second crossing direction DR2a may be perpendicular to each other. In the present disclosure, the first direction DR1 may be defined as a column direction, and the second direction DR2 may be defined as a row direction.

The light emitting areas PXA1, PXA2, and PXA3 may include first light emitting areas PXA1, second light emitting areas PXA2, and third light emitting areas PXA3. The first, second, and third light emitting areas PXA1, PXA2, and PXA3 may be areas that emit lights of different colors. In detail, the first light emitting areas PXA1 may be areas that emit the light of a first color, the second light emitting areas PXA2 may be areas that emit the light of a second color, and the third light emitting areas PXA3 may be areas that emit the light of a third color. For example, the first light emitting areas PXA1 may emit a red light, the second light emitting areas PXA2 may emit a blue light, and the third light emitting areas PXA3 may emit a green light. However, embodiments according to the present disclosure are not limited thereto or thereby, and the colors of the lights emitted through the first, second, and third light emitting areas PXA1, PXA2, and PXA3 may be selected as a combination of three colors that produces a white light when mixed. Alternatively, the first, second, and third light emitting areas PXA1, PXA2, and PXA3 may be areas that emit lights of the same color.

The light emitting openings may include a first light emitting opening group OP-P1, a second light emitting opening group OP-P2, and a third light emitting opening group OP-P3. The light emitting openings of the first light emitting opening group OP-P1 may respectively correspond to the first light emitting areas PXA1. The light emitting openings of the second light emitting opening group OP-P2 may respectively correspond to the second light emitting areas PXA2. The light emitting openings of the third light emitting opening group OP-P3 may respectively correspond to the third light emitting areas PXA3. For example, the light emitting openings of the first light emitting opening group OP-P1 may correspond to the areas from which the red light is emitted, the light emitting openings of the second light emitting opening group OP-P2 may correspond to the areas from which the blue light is emitted, and the light emitting openings of the third light emitting opening group OP-P3 may correspond to the areas from which the green light is emitted.

The light emitting openings of the first, second, and third light emitting opening groups OP-P1, OP-P2, and OP-P3 may have different areas when viewed in the plane (or in a plan view). As an example, among the first, second, and third light emitting opening groups OP-P1, OP-P2, and OP-P3, the light emitting openings defined in the second light emitting opening group OP-P2 may have the largest area, and the light emitting openings defined in the third light emitting opening group OP-P3 may have the smallest area. However, embodiments according to the present disclosure are not limited thereto or thereby, and the area of each light emitting opening may be designed in consideration of the light emission efficiency of the color characteristics and light emission efficiency of light emitted through the light-emitting opening. Each of the first, second, and third light emitting opening groups OP-P1, OP-P2, and OP-P3 may include the light emitting openings extending in one direction. Each of the first, second, and third light emitting opening groups OP-P1, OP-P2, and OP-P3 may include the light emitting openings (hereinafter, respectively referred to as a first light emitting opening OP-P11, a third light emitting opening OP-P21, and a fifth light emitting opening OP-P31) extending in the first crossing direction DR1a and the light emitting openings (hereinafter, respectively referred to as a second light emitting opening OP-P12, a fourth light emitting opening OP-P22, and a sixth light emitting opening OP-P32) extending in the second crossing direction DR2a.

In detail, referring to the first light emitting opening group OP-P1, the first light emitting opening group OP-P1 may include the first light emitting opening OP-P11 and the second light emitting opening OP-P12, which extend in different directions. The area of the first light emitting opening OP-P11 and the area of the second light emitting opening OP-P12, which are included in the first light emitting opening group OP-P1, may be the same as each other.

In FIG. 8, the light emitting openings of the first, second, and third light emitting opening groups OP-P1, OP-P2, and OP-P3 are shown as having a rectangular shape extending in one direction, however, embodiments according to the present disclosure are not limited thereto or thereby. According to some embodiments, at least one of the light emitting openings may have a polygonal or elliptical shape extending in one direction, and the shapes of the light emitting openings may be modified in various way.

The light emitting openings of the first, second, and third light emitting opening groups OP-P1, OP-P2, and OP-P3 may be arranged in a specific rule.

The light emitting openings of the first light emitting opening group OP-P1 and the light emitting openings of the second light emitting opening group OP-P2 may be alternately arranged with each other along the first direction DR1 and the second direction DR2. As an example, the first light emitting opening OP-P11 and the third light emitting opening OP-P21 may be arranged along the first direction DR1, and the second light emitting opening OP-P12 and the fourth light emitting opening OP-P22 may be arranged along the first direction DR1. The first light emitting opening OP-P11 and the fourth light emitting opening OP-P22 may be arranged along the second direction DR2.

The light emitting openings of the third light emitting opening group OP-P3 may be arranged along the first direction DR1 and the second direction DR2. As an example, the fifth light emitting openings OP-P31 and the sixth light emitting openings OP-P32 of the third light emitting opening group OP-P3 may be alternately arranged with each other along the first direction DR1 and the second direction DR2.

The light emitting openings of the first and second light emitting opening groups OP-P1 and OP-P2 may be arranged in a staggered manner with respect to the light emitting openings of the third light emitting opening group OP-P3 along the first direction DR1. Some of the light emitting openings of the third light emitting opening group OP-P3 and the light emitting openings of the first light emitting opening group OP-P1 may be arranged along the first crossing direction DR1a, and the remaining light emitting openings of the third light emitting opening group OP-P3 and the light emitting openings of the second light emitting opening group OP-P2 may be arranged along the first crossing direction DR1a.

As an example, the first light emitting opening OP-P11 and the second light emitting opening OP-P12 may be arranged along the first crossing direction DR1a such that the fifth light emitting opening OP-P31 is located between the first light emitting opening OP-P11 and the second light emitting opening OP-P12. Each of the third light emitting opening OP-P21 and the fourth light emitting opening OP-P22 may be arranged along the first crossing direction DR1a with the sixth light emitting opening OP-P32. The third light emitting opening OP-P21 and the fourth light emitting opening OP-P22 may be arranged along the second crossing direction DR2a such that the fifth light emitting opening OP-P31 is located between the third light emitting opening OP-P21 and the fourth light emitting opening OP-P22.

The arrangement of the first, second, and third light emitting opening groups OP-P1, OP-P2, and OP-P3 shown in FIG. 8 is merely an example and should not be particularly limited.

According to some embodiments, a first insulating layer LRL may be located in the non-light-emitting area NPXA. The first insulating layer LRL may be a component of the light control layer LCL shown in FIG. 4. The first insulating layer LRL may have a mesh shape. The first insulating layer LRL may be arranged not to overlap with the light emitting areas PXA1, PXA2, and PXA3.

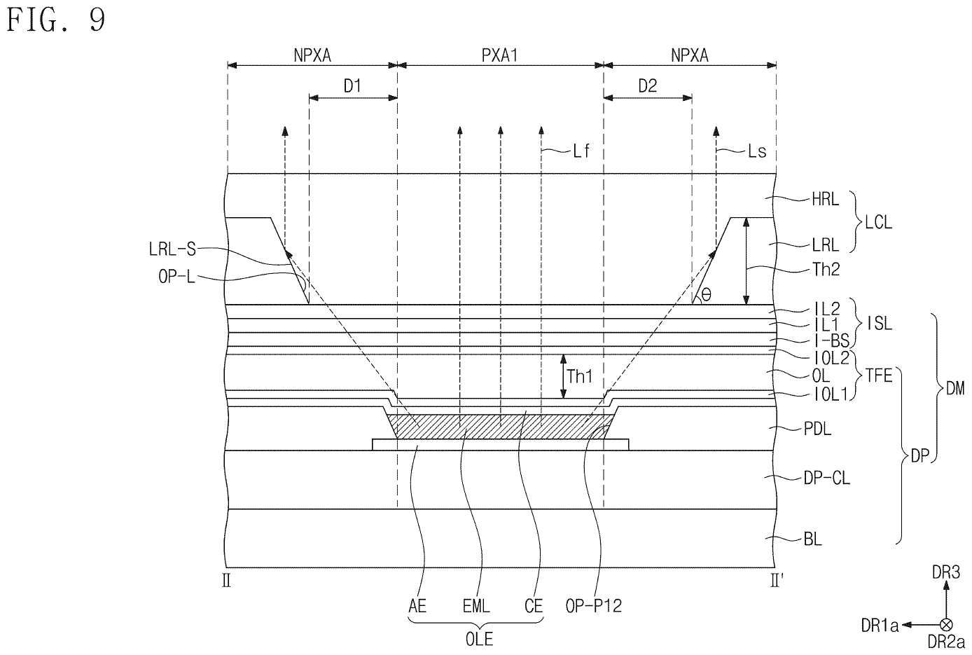

FIG. 9 is a cross-sectional view of the display device taken along a line II-II′ of FIG. 8 according to some embodiments of the present disclosure. FIG. 9 is a cross-sectional view of the second light emitting opening OP-P12 among the light emitting openings shown in FIG. 8. The following descriptions may be applied equally to other light emitting openings and openings.

Referring to FIG. 9, the display module DM may include the display panel DP and the input sensing layer ISL. The display panel DP may include the base layer BL, a circuit element layer DP-CL, the light emitting element OLE, the pixel definition layer PDL, and an encapsulation layer TFE.

The display panel DP may include a plurality of insulating layers, a semiconductor pattern, a conductive pattern, and a signal line. In the process of manufacturing the display panel DP, an insulating layer, a semiconductor layer, and a conductive layer may be formed on the base layer BL by a coating or depositing process. Then, the insulating layer, the semiconductor layer, and the conductive layer may be selectively patterned through a photolithography process. Accordingly, the semiconductor pattern, the conductive pattern, and the signal line, which are included in the circuit element layer DP-CL and the light emitting element OLE, may be formed.

The semiconductor pattern may be arranged over the pixels in a selected rule. Each of the pixels may have an equivalent circuit including transistors, at least one capacitor, and a light emitting element, and the equivalent circuit of the pixel may be changed in various ways.

The base layer BL may provide a base surface on which the circuit element layer DP-CL is located. The base layer BL may include a glass substrate, a metal substrate, or an organic/inorganic composite material substrate.

The base layer BL may have a multi-layer structure. As an example, the base layer BL may include synthetic resin layers and at least one inorganic layer located between the synthetic resin layers. As an example, the synthetic resin layer of the base layer BL may include an acrylic-based resin, a methacrylic-based resin, a polyisoprene-based resin, a vinyl-based resin, an epoxy-based resin, a urethane-based resin, a cellulose-based resin, a siloxane-based resin, a polyamide-based resin, a perylene-based resin, or a polyimide-based resin, however, materials for the base layer BL should not be limited thereto or thereby.

At least one inorganic layer may be located on an upper surface of the base layer BL. The inorganic layers may constitute a barrier layer and/or a buffer layer. The inorganic layer located on the base layer BL may increase an adhesion between the base layer BL and the semiconductor pattern of the circuit element layer DP-CL. As an example, the inorganic layer may include at least one of aluminum oxide, titanium oxide, silicon oxide, silicon nitride, silicon oxynitride, zirconium oxide, or hafnium oxide.

The circuit element layer DP-CL may be located on the base layer BL. The circuit element layer DP-CL may include at least one insulating layer and a circuit element. The insulating layer included in the circuit element layer DP-CL may be referred to as an intermediate insulating layer. The circuit element layer DP-CL may include the driving circuit GDC, the signal lines SGL, and the pad part PLD shown in FIG. 3. The pixel pads D-PD and the input pads I-PD may be provided by exposing a portion of the wirings located in the circuit element layer DP-CL through the intermediate insulating layer of the circuit element layer DP-CL.

The semiconductor pattern included in the circuit element layer DP-CL may be arranged in a selected rule to overlap with the light emitting areas when viewed in the plane (or in a plan view). The semiconductor pattern may include polysilicon, amorphous silicon, or metal oxide.

According to some embodiments, the semiconductor pattern may have different electrical properties depending on whether it is doped or reduced. The semiconductor pattern may include a first area having high conductivity and a second area having low conductivity.

For example, the first area may be doped with an N-type dopant or a P-type dopant. A P-type transistor may include a doped region doped with the P-type dopant, and an N-type transistor may include a doped region doped with the N-type dopant. The second area may be a non-doped region or a region doped at a lower concentration than the first area.

However, embodiments according to the present disclosure are not limited thereto. The first area may be an area in which a metal oxide is reduced, and the second area may be an area in which the metal oxide is not reduced.

The conductivity of the first area may be higher than that of the second area, and the first area may substantially serve as an electrode or a signal line. The second area may substantially correspond to an active area (or a channel area) of a transistor. In other words, a portion of the semiconductor pattern may serve as the active area of the transistor, and another portion may serve as a source area or a drain area of the transistor.

The light emitting element OLE may be located on the circuit element layer DP-CL. The light emitting element OLE may include a first electrode AE, a light emitting layer EML, and a second electrode CE, however, embodiments according to the present disclosure are not limited thereto. According to some embodiments, the light emitting element OLE may further include a hole control layer and an electron control layer.

The first electrode AE may be located on the circuit element layer DP-CL. The first electrode AE may be electrically connected to the transistor of the circuit element layer DP-CL via a contact hole defined through the intermediate insulating layer of the circuit element layer DP-CL.

The pixel definition layer PDL may be located on the first electrode AE. As described above, the light emitting openings may be defined through the pixel definition layer PDL, and hereinafter, the second light emitting opening OP-P12 shown in FIG. 9 will be described as a representative example. These descriptions may be equally applied to other light emitting openings.

A portion of the first electrode AE may be exposed through the second light emitting opening OP-P12 of the pixel definition layer PDL. The pixel definition layer PDL may cover the other portion of the first electrode AE except the portion of the first electrode AE, which is exposed through the second light emitting opening OP-P12. When viewed in the plane (or in a plan view), portions of the first electrode AE, which are exposed through the light emitting openings of the pixel definition layer PDL, may correspond to the light emitting areas.

The pixel definition layer PDL may include an organic material. According to some embodiments, the pixel definition layer PDL may have a black color. For example, the pixel definition layer PDL may include a base resin and a black pigment and/or black dye mixed with the base resin.

The light emitting layer EML may be located on the first electrode AE. The light emitting layer EML may be located in an area corresponding to the second light emitting opening OP-P12 of the pixel definition layer PDL. The light emitting layer EML may include an organic light emitting material, an inorganic light emitting material, a quantum dot, or a quantum rod.

The light emitting layer EML may be separated into portions to correspond to the light emitting areas, respectively. The individually formed light emitting layers EML may each emit light having at least one color among red, green, and blue colors, however, embodiments according to the present disclosure are not limited thereto or thereby. According to some embodiments, the light emitting layer EML may be commonly formed over the light emitting areas and may emit a blue or white light. Alternatively, the light emitting layer EML may have a multi-layer structure called a tandem structure.

The second electrode CE may be located on the light emitting layer EML. The second electrode CE may be commonly arranged over the light emitting areas, for example, the first light emitting area PXA1 of FIG. 9, and the non-light-emitting area NPXA. A common voltage may be applied to the second electrode CE, and the second electrode CE may be referred to as a common electrode.

The encapsulation layer TFE may be located on the second electrode CE. The encapsulation layer TFE may include an inorganic layer and an organic layer. As an example, the encapsulation layer TFE may include a first inorganic layer IOL1, an organic layer OL, and a second inorganic layer IOL2. This three-layer structure may be defined as a thin film encapsulation layer.

The first inorganic layer IOL1 and the second inorganic layer IOL2 may protect the light emitting element OLE from moisture and/or oxygen. For example, the first inorganic layer IOL1 and the second inorganic layer IOL2 may include a silicon nitride layer, a silicon oxynitride layer, a silicon oxide layer, a titanium oxide layer, or an aluminum oxide layer, but they should not be particularly limited. The organic layer OL may protect the light emitting element OLE from a foreign substance such as dust particles. The organic layer OL may include an acrylic-based organic layer, but it should not be particularly limited.

The input sensing layer ISL may be located on the display panel DP. For example, the input sensing layer ISL may be located directly on the display panel DP. The input sensing layer ISL may include a plurality of conductive layers and a plurality of touch insulating layers. The conductive layers of the input sensing layer ISL may constitute the sensing electrodes and the signal lines shown in FIG. 7. The conductive layers may include a first conductive layer and a second conductive layer. The touch insulating layers may include a base insulating layer I-BS, a first touch insulating layer IL1, and a second touch insulating layer IL2.

The base insulating layer I-BS may be located on the encapsulation layer TFE. The base insulating layer I-BS may include an inorganic material. As an example, the base insulating layer I-BS may include silicon nitride. Although both the inorganic layer located on an uppermost position of the encapsulation layer TFE and the base insulating layer I-BS may include silicon nitride, the inorganic layer of the encapsulation layer TFE and the base insulating layer I-BS may be formed under different deposition conditions.

The first touch insulating layer IL1 may be located on the base insulating layer I-BS. The first touch insulating layer IL1 may include the same material as the base insulating layer I-BS. The first touch insulating layer IL1 may have a thickness smaller than a thickness of the base insulating layer I-BS. According to some embodiments, the first touch insulating layer IL1 may be omitted.

The first conductive layer may be located on the first touch insulating layer IL1. The first conductive layer may include the first connection part CP1 of FIG. 7, however, embodiments according to the present disclosure are not limited thereto or thereby. According to some embodiments, the first conductive layer may include the first and second sensor parts SP1 and SP2 and the second connection part CP2 of FIG. 7.

The second touch insulating layer IL2 may be located on the first touch insulating layer IL1 and may cover the first conductive layer. The second conductive layer may be located on the second touch insulating layer IL2. The second conductive layer may include the first sensor part SP1, the second sensor part SP2, and the second connection part CP2 of FIG. 7, however, embodiments according to the present disclosure are not limited thereto or thereby. According to some embodiments, the second conductive layer may include the first connection part CP1 of FIG. 7.

The second touch insulating layer IL2 may include the same material as the base insulating layer I-BS. The second touch insulating layer IL2 may have a thickness smaller than the thickness of the base insulating layer I-BS. The first conductive layer and the second conductive layer may be spaced apart from each other by the second touch insulating layer IL2 when viewed in a cross-section. A contact hole may be defined through the second touch insulating layer IL2 to expose a portion of the first conductive layer.

The light control layer LCL may be located on the input sensing layer ISL. Different from the display device DD shown in FIG. 5A, the first adhesive layer AF1 is omitted from between the light control layer LCL and the input sensing layer ISL as shown in FIG. 9. That is, the light control layer LCL may be located directly on the input sensing layer ISL.

The light control layer LCL may include the first insulating layer LRL and a second insulating layer HRL covering the first insulating layer LRL.

The first insulating layer LRL may be located on the input sensing layer ISL. In detail, the first insulating layer LRL may be located directly on the input sensing layer ISL. An opening OP-L may be defined through the first insulating layer LRL to correspond to the second light emitting opening OP-P12. According to some embodiments, a plurality of openings may be defined through the first insulating layer LRL to overlap with the light emitting openings shown in FIG. 8. FIG. 9 shows a cross-section of the opening OP-L corresponding to the second light emitting opening OP-P12.

The second insulating layer HRL may be located on the first insulating layer LRL. As an example, the second insulating layer HRL may be located directly on the first insulating layer LRL. The second insulating layer HRL may be arranged to overlap with the light emitting areas, e.g., the first light emitting area PXA1 shown in FIG. 9, and the non-light-emitting area NPXA. The second insulating layer HRL may cover an upper surface of the first insulating layer LRL and an inner side of the openings in the first insulating layer LRL.

The cross-section of the opening OP-L of the first insulating layer LRL may include a slant surface LRL-S. The slant surface LRL-S may be slanted with respect to an upper surface of the second touch insulating layer IL2. The second insulating layer HRL may cover the slant surface LRL-S of the first insulating layer LRL. An angle (θ) between the slant surface LRL-S (or the inner side surface of the first insulating layer LRL) and the upper surface of the second touch insulating layer IL2 (or the lower surface of the first insulating layer LRL) may be an acute angle. According to some embodiments, the angle (θ) may be within a range greater than or equal to about 65° and smaller than or equal to about 80°.

Each of the first insulating layer LRL and the second insulating layer HRL may have a selected refractive index. The refractive index of the second insulating layer HRL may be greater than that of the first insulating layer LRL. Accordingly, a total reflection phenomenon may occur at an interface between the first insulating layer LRL and the second insulating layer HRL.

The refractive index of the first insulating layer LRL may be greater than or equal to about 1.3 and smaller than or equal to about 1.6. In detail, the refractive index of the first insulating layer LRL may be greater than or equal to about 1.4 and smaller than or equal to about 1.44. The first insulating layer LRL may include an acrylic-based organic material having a refractive index of approximately 1.5. As an example, the first insulating layer LRL may include at least one of ethylhexyl acrylate, pentafluoropropyl acrylate, poly(ethylene glycol) dimethacrylate, or ethylene glycol dimethacrylate. However, the material of the first insulating layer LRL should not be limited thereto or thereby.

The refractive index of the second insulating layer HRL may be greater than or equal to about 1.6 and smaller than or equal to about 1.9. In detail, the refractive index of the second insulating layer HRL may be greater than or equal to about 1.65 and smaller than or equal to about 1.85. The second insulating layer HRL may include an acrylic-based or siloxane-based organic material having a refractive index of about 1.6. As an example, the second insulating layer HRL may include at least one of methyltrimethoxysilane, tetramethoxysilane, or polydiarylsiloxane. However, the material of the second insulating layer HRL should not be limited thereto or thereby.

According to some embodiments, the second insulating layer HRL may further include dispersion particles to have a relatively high refractive index. For example, the second insulating layer HRL may further include metal oxide particles such as zinc oxide (ZnOₓ), titanium oxide (TiO₂), or zirconium oxide (ZrO₂).

The light emitted from the light emitting element OLE may be emitted in a front direction and a side direction. The light emission efficiency of the display device DD may be enhanced by the light emitted in the front direction. FIG. 9 schematically shows, for convenience of explanation, a light path of a front light Lf emitted from the light emitting element OLE toward the front direction and a side light Ls emitted from the light emitting element OLE toward the side direction. However, the light paths are shown only for illustrative purposes and the light paths should not be limited thereto or thereby.

According to some embodiments of the present disclosure, the front light Lf emitted toward the front direction from the light emitting element OLE may pass through the second insulating layer HRL and may exit from the second insulating layer HRL. Among the side lights emitted toward the side direction from the light emitting element OLE, a portion of the side light Ls may be incident into the slant surface LRL-S, which is an interface between the first insulating layer LRL and the second insulating layer HRL. The side light Ls incident into the slant surface LRL-S of the first insulating layer LRL may be refracted or totally reflected due to the difference in refractive index between the first insulating layer LRL and the second insulating layer HRL. The light path of the side light Ls undergoing the total reflection may be redirected toward the front direction. As described above, because the light path of the side light Ls is redirected toward the front direction, the light emission efficiency of the display device DD may be relatively improved.

According to some embodiments of the present disclosure, a width of the opening OP-L and a width of the second light emitting opening OP-P12 may be different from each other. Referring to FIGS. 8 and 9, a distance between a first side S1 defining the second light emitting opening OP-P12 and a second side S2 defining the opening OP-L may be defined as a first distance D1. Similarly, a distance between a third side S3 defining the second light emitting opening OP-P12 and a fourth side S4 defining the opening OP-L that are respectively symmetric to the first side S1 and the second side S2 with respect to the light emitting element OLE may be defined as a second distance D2. The difference between the width of the opening OP-L and the width of the second light emitting opening OP-P12 may be equal to a sum of the first distance D1 and the second distance D2. According to some embodiments, the first distance D1 and the second distance D2 may be identical.

According to some embodiments, each of the first distance D1 and the second distance D2 may be greater than or equal to about 4 μm and smaller than or equal to about 6 μm. As an example, each of the first distance D1 and the second distance D2 may be about 6 μm.

A thickness of the organic layer OL overlapping with the second light emitting opening OP-P12 may be defined as a first thickness Th1, and a thickness of the first insulating layer LRL may be defined as a second thickness Th2. According to some embodiments, the first thickness Th1 may be smaller than the second thickness Th2. As an example, the first thickness Th1 may be greater than or equal to about 2 μm and smaller than or equal to about 6 μm, and the second thickness Th2 may be greater than or equal to about 4 μm and smaller than or equal to about 6 μm.

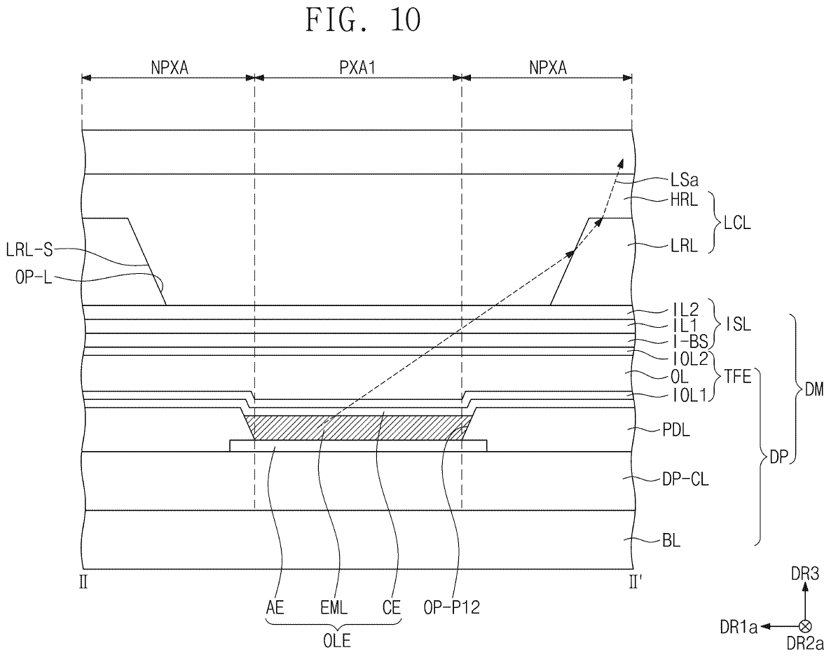

FIG. 10 is a cross-sectional view of a portion of the display device according to some embodiments of the present disclosure. In detail, FIG. 10 is a view to explain a light path of a side light Lsa emitted toward the side direction from the light emitting element OLE. Descriptions of elements identical to those previously described will be omitted.

Referring to FIG. 10, the side light Lsa among the side lights emitted toward the side direction from the light emitting element OLE may be incident into the slant surface LRL-S, which is the interface between the first insulating layer LRL and the second insulating layer HRL. The side light Lsa incident into the slant surface LRL-S of the first insulating layer LRL may be refracted or totally reflected due to the difference in refractive index between the first insulating layer LRL and the second insulating layer HRL.

Referring to FIGS. 9 and 10, the side light Lsa may be a light emitted from a central portion of the light emitting element OLE. As the thickness of the first insulating layer LRL increases, the light emission efficiency of the side light Lsa to the outside may decrease. That is, a luminance at a 45° viewing angle may be reduced due to a decrease in the side light Lsa. In addition, as the first distance D1 and the second distance D2 become larger, the front light emission efficiency of the side light Ls may decrease.

The display device DD (refer to FIG. 4) with relatively improved light emission efficiency may be provided by adjusting the width difference between the second light emitting opening OP-P12 of the pixel definition layer PDL and the opening OP-L of the first insulating layer LRL, for example, the first distance D1 and the second distance D2, to a selected value and by adjusting the second thickness Th2 of the first insulating layer LRL to a selected value.

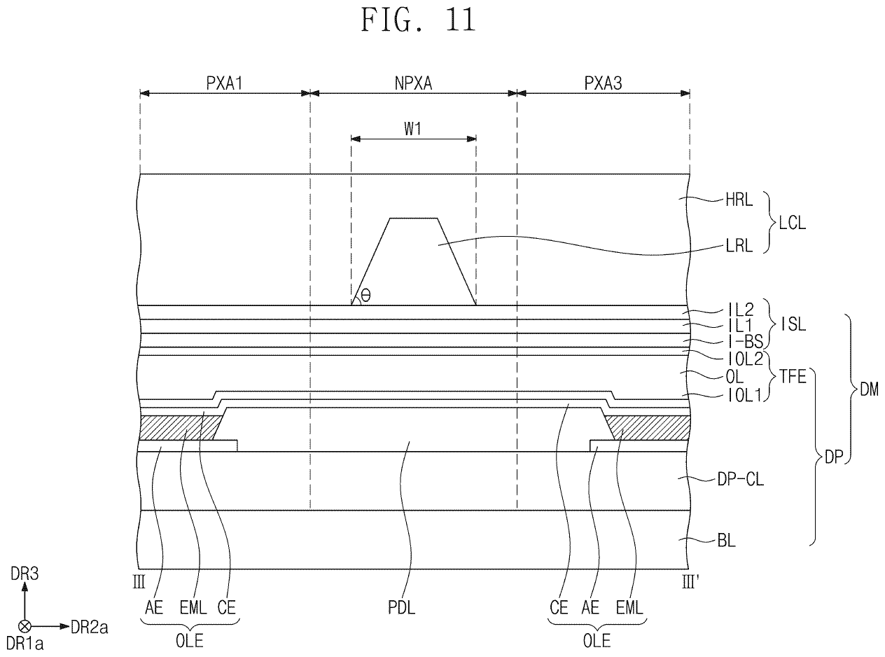

FIG. 11 is a cross-sectional view of the display device taken along a line III-III′ of FIG. 8 according to some embodiments of the present disclosure.

Referring to FIG. 11, the first insulating layer LRL may have a trapezoidal shape in the cross-section. The first insulating layer LRL may have a first width W1. According to some embodiments, the first width W1 may be equal to the first distance D1 or the second distance D2 shown in FIG. 9. As an example, the first width W1 may be greater than or equal to about 4 μm and smaller than or equal to about 6 μm. The pixel definition layer PDL may have a width of about 18 μm when viewed in the cross-section.

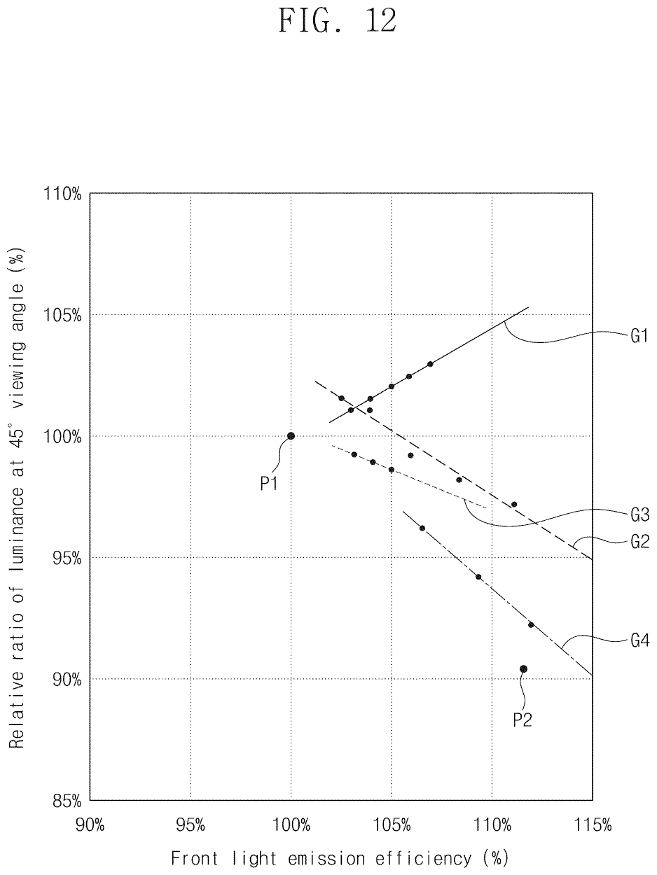

FIG. 12 is a diagram representing graphs of a side luminance and a front light emission efficiency of the display device according to some embodiments of the present disclosure. In detail, FIG. 12 is a diagram representing graphs of the side luminance and the front light emission efficiency of the display device DD (refer to FIG. 4) according to the first distance D1 or the second distance D2 of FIG. 8, the thickness Th2 of the first insulating layer LRL, and the angle (θ) between the slant surface LRL-S and the upper surface of the second touch insulating layer IL2.

Hereinafter, Table 1 shows the front light emission efficiency and a luminance ratio at a 45° viewing angle according to comparative examples and embodiment examples.

TABLE 1

| | | Front light | | Relative ratio |
|---|---|---|---|---|
| | | emission | Luminance | of luminance |
| | Thickness | efficiency | ratio at 45° | ratio at 45° |
| | (μm) | (%) | viewing angle | viewing angle |
| Comparative | — | 100 | 54 | 100 |
| example 1 | | | | |
| Comparative | 2 | 112 | 49 | 90 |
| example 2 | | | | |
| Embodiment | 2 | 103 | 54 | 99 |
| example 1 | 3 | 104 | 54 | 99 |
| | 4 | 105 | 54 | 99 |
| Embodiment | 2 | 103 | 55 | 101 |
| example 2 | 3 | 104 | 55 | 102 |
| | 4 | 105 | 55 | 102 |
| | 5 | 106 | 56 | 102 |
| | 6 | 107 | 56 | 103 |
| Embodiment | 2 | 107 | 52 | 96 |
| example 3 | 3 | 109 | 51 | 94 |
| | 4 | 112 | 50 | 92 |
| Embodiment | 2 | 102 | 55 | 102 |
| example 4 | 3 | 104 | 55 | 101 |
| | 4 | 106 | 54 | 99 |
| | 5 | 108 | 53 | 98 |
| | 6 | 111 | 53 | 97 |

In Table 1, comparative example 1 corresponds to a display device in which the light control layer LCL shown in FIG. 9 is omitted, and comparative example 2 corresponds to a display device in which the first distance D1 and the second distance D2 shown in FIG. 9 are zero (0).

In addition, embodiment example 1 corresponds to a display device in which the first distance D1 and the second distance D2 shown in FIG. 9 are 4 μm and the angle (θ) between the slant surface LRL-S and the upper surface of the second touch insulating layer IL2 is 70°. Embodiment example 2 corresponds to a display device in which the first distance D1 and the second distance D2 shown in FIG. 9 are 6 μm and the angle (θ) between the slant surface LRL-S and the upper surface of the second touch insulating layer IL2 is 70°. Embodiment example 3 corresponds to a display device in which the first distance D1 and the second distance D2 shown in FIG. 9 are 4 μm and the angle (θ) between the slant surface LRL-S and the upper surface of the second touch insulating layer IL2 is 75°. Embodiment example 4 corresponds to a display device in which the first distance D1 and the second distance D2 shown in FIG. 9 are 6 μm and the angle (θ) between the slant surface LRL-S and the upper surface of the second touch insulating layer IL2 is 75°.

Referring to the values in Table 1, based on the front light emission efficiency of comparative example 1 that is taken as a reference (100%), the front light emission efficiencies described in comparative example 2, embodiment example 1, embodiment example 2, embodiment example 3, and embodiment example 4 represent relative values with respect to the front light emission efficiency of comparative example 1.

In addition, based on the luminance ratio at the 45° viewing angle of comparative example 1 that is taken as a reference (100%), the relative ratio of luminance ratios at the 45° viewing angle described in comparative example 2, embodiment example 1, embodiment example 2, embodiment example 3, and embodiment example 4 represent relative values with respect to the luminance ratio at the 45° viewing angle of comparative example 1.

Referring to FIG. 12 and Table 1, a first point P1 represents comparative example 1, and a second point P2 represents comparative example 2. That is, when the first distance D1 and the second distance D2 are zero, as in comparative example 2, it is observed that the front light emission efficiency increases, but the luminance ratio at the 45° viewing angle decreases.

A first graph G1 represents the front light emission efficiency and relative ratio of the luminance ratio at the 45° viewing angle of embodiment example 1 in Table 1, a second graph G2 represents the front light emission efficiency and relative ratio of the luminance ratio at the 45° viewing angle of embodiment example 2, a third graph G3 represents the front light emission efficiency and relative ratio of the luminance ratio at the 45° viewing angle of embodiment example 3, and a fourth graph G4 represents the front light emission efficiency and relative ratio of the luminance ratio at the 45° viewing angle of embodiment example 4.

That is, referring to FIGS. 8 and 12 together with Table 1, it is observed that, as in embodiment example 2, the front light emission efficiency and relative ratio of the luminance ratio at the 45° viewing angle simultaneously increases when the distances, e.g., the first distance D1 and the second distance D2, are 6 μm, the angle (θ) between the slant surface LRL-S and the upper surface of the second touch insulating layer IL2 is 70°, and the thickness Th2 of the first insulating layer LRL is 6 μm.

As another example, mapping tables according to the angle (θ) between the slant surface and the upper surface of the second touch insulating layer IL2, the refractive index of the second insulating layer HRL, the distances (e.g., the first distance D1 and the second distance D2), and the thickness Th1 of the organic layer OL are presented below.

TABLE 2

| Angle | Refractive | Distance | Thickness of organic layer (μm) | | | | |
|---|---|---|---|---|---|---|---|
| (°) | index | (μm) | 2 | 4 | 6 | 8 | 10 |
| 65 | 1.61 | 1 | TRUE | TRUE | TRUE | FALSE | FALSE |
| | | 2 | TRUE | TRUE | TRUE | TRUE | TRUE |
| | | 3 | TRUE | TRUE | TRUE | TRUE | TRUE |
| | | 4 | TRUE | TRUE | TRUE | TRUE | TRUE |
| | | 5 | TRUE | TRUE | TRUE | TRUE | TRUE |
| | | 6 | TRUE | TRUE | TRUE | TRUE | TRUE |

TABLE 3

| Angle | Refractive | Distance | Thickness of organic layer (μm) | | | | |
|---|---|---|---|---|---|---|---|
| (°) | index | (μm) | 2 | 4 | 6 | 8 | 10 |
| 70 | 1.61 | 1 | FALSE | FALSE | FALSE | FALSE | FALSE |
| | | 2 | TRUE | FALSE | FALSE | FALSE | FALSE |
| | | 3 | TRUE | TRUE | TRUE | FALSE | FALSE |
| | | 4 | TRUE | TRUE | TRUE | FALSE | FALSE |
| | | 5 | TRUE | TRUE | TRUE | TRUE | FALSE |
| | | 6 | TRUE | TRUE | TRUE | TRUE | TRUE |

TABLE 4

| Angle | Refractive | Distance | Thickness of organic layer (μm) | | | | |
|---|---|---|---|---|---|---|---|
| (°) | index | (μm) | 2 | 4 | 6 | 8 | 10 |
| 65 | 1.65 | 1 | TRUE | TRUE | FALSE | FALSE | FALSE |
| | | 2 | TRUE | TRUE | TRUE | FALSE | FALSE |
| | | 3 | TRUE | TRUE | TRUE | TRUE | TRUE |
| | | 4 | TRUE | TRUE | TRUE | TRUE | TRUE |
| | | 5 | TRUE | TRUE | TRUE | TRUE | TRUE |
| | | 6 | TRUE | TRUE | TRUE | TRUE | TRUE |

TABLE 5

| Angle | Refractive | Distance | Thickness of organic layer (μm) | | | | |
|---|---|---|---|---|---|---|---|
| (°) | index | (μm) | 2 | 4 | 6 | 8 | 10 |
| 70 | 1.65 | 1 | FALSE | FALSE | FALSE | FALSE | FALSE |
| | | 2 | FALSE | FALSE | FALSE | FALSE | FALSE |
| | | 3 | TRUE | FALSE | FALSE | FALSE | FALSE |
| | | 4 | TRUE | TRUE | FALSE | FALSE | FALSE |
| | | 5 | TRUE | TRUE | FALSE | FALSE | FALSE |
| | | 6 | TRUE | TRUE | TRUE | FALSE | FALSE |

In Tables 2 to 5, the angles may correspond to the angle (θ) between the slant surface and the upper surface of the second touch insulating layer IL2 of FIG. 9, the refractive index may correspond to the refractive index of the second insulating layer HRL, the distances may correspond to the first distance D1 and the second distance D2, and the thickness may correspond to the thickness Th1 of the organic layer OL.

In Tables 2 to 5, embodiments are marked as TRUE when both the front light emission efficiency and relative ratio of the luminance ratio at the 45° viewing angle increase simultaneously as in the second graph G2 shown in FIG. 12, and embodiments are marked as FALSE when the front light emission efficiency increases but relative ratio of the luminance ratio at the 45° viewing angle decreases.

That is, referring to Tables 2 to 5, it is observed that both the front light emission efficiency and relative ratio of the luminance ratio at the 45° viewing angle increase simultaneously under certain range of conditions. By adjusting the distances, e.g., the first distance D1 and the second distance D2, and the thickness Th1 of the organic layer OL to selected values, the light emission efficiency of the display device DD (refer to FIG. 4) may be relatively improved.

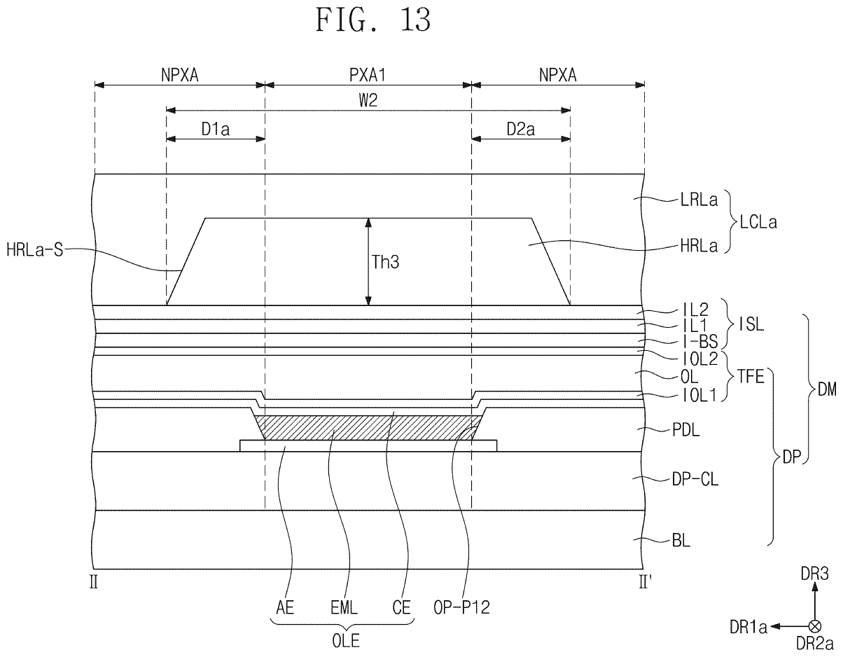

FIG. 13 is a cross-sectional view of a portion of a display device according to some embodiments of the present disclosure.

Referring to FIG. 13, a light control layer LCLa may be located on an input sensing layer ISL. The light control layer LCLa may include a second insulating layer HRLa and a first insulating layer LRLa covering the second insulating layer HRLa. The second insulating layer HRLa may be referred to as an organic pattern, and the first insulating layer LRLa may be referred to as an insulating layer.

The organic pattern HRLa may be located on the input sensing layer ISL. In detail, the organic pattern HRLa may be located directly on the input sensing layer ISL. The organic pattern HRLa may overlap a first light emitting area PXA1.

The organic pattern HRLa may have a second width W2. The second width W2 may be greater than a width of a second light emitting opening OP-P12. According to some embodiments, a distance between one end of the organic pattern HRLa and one end of the second light emitting opening OP-P12 may be referred to as a first distance D1a, and a distance between the other end of the organic pattern HRLa and the other end of the second light emitting opening OP-P12, which corresponds to the other end of the organic pattern HRLa, may be referred to as a second distance D2a. A difference in width between the organic pattern HRLa and the second light emitting opening OP-P12 may be equal to a sum of the first distance D1a and the second distance D2a. According to some embodiments, the first distance D1a may be equal to the second distance D2a.

According to some embodiments, each of the first distance D1a and the second distance D2a may be greater than or equal to about 4 μm and smaller than or equal to about 6 μm. As an example, each of the first distance D1a and the second distance D2a may be about 6 μm.

The organic pattern HRLa may have a trapezoidal shape when viewed in a cross-section. The organic pattern HRLa may include a slant surface HRLa-S. The slant surface HRLa-S may be slanted with respect to an upper surface of a second touch insulating layer IL2. The insulating layer LRLa may cover the slant surface HRLa-S of the organic pattern HRLa. An angle (θ) between the slant surface HRLa-S and the upper surface of the second touch insulating layer IL2 may be an acute angle. According to some embodiments, the angle (θ) between the slant surface HRLa-S and the upper surface of the second touch insulating layer IL2 may be greater than or equal to about 65° and smaller than or equal to about 80°.

A thickness of the organic pattern HRLa may be referred to as a third thickness Th3. As an example, the third thickness Th3 may be greater than or equal to about 4 μm and smaller than or equal to about 6 μm.

Each of the organic pattern HRLa and the insulating layer LRLa may have a selected refractive index. The refractive index of the organic pattern HRLa may be greater than the refractive index of the insulating layer LRLa. Accordingly, a total reflection phenomenon may occur at an interface between the organic pattern HRLa and the insulating layer LRLa. The refractive index of the organic pattern HRLa may be greater than or equal to about 1.6 and smaller than or equal to about 1.9. In detail, the refractive index of the organic pattern HRLa may be greater than or equal to about 1.65 and smaller than or equal to about 1.85. The refractive index of the insulating layer LRLa may be greater than or equal to about 1.3 and smaller than or equal to about 1.6. In detail, the refractive index of the insulating layer LRLa may be greater than or equal to about 1.4 and smaller than or equal to about 1.55.

Although the embodiments of the present disclosure have been described, it is understood that the present disclosure should not be limited to these embodiments but various changes and modifications can be made by one ordinary skilled in the art within the spirit and scope of the present disclosure as hereinafter claimed.

Therefore, the disclosed subject matter should not be limited to any single embodiment described herein, and the scope of the present inventive concept shall be determined according to the attached claims, and their equivalents.

What is claimed is:

1. A display device comprising:
a display panel;
a first insulating layer on the display panel and having a first refractive index; and
a second insulating layer on the first insulating layer and having a second refractive index different from the first refractive index, the display panel comprising:
a pixel definition layer through which a light emitting opening comprising a first side extending in a first direction is defined; and
a light emitting element in the light emitting opening, wherein an opening comprising a second side extending in the first direction is defined through the first insulating layer to overlap with the light emitting opening, and a distance between the first side and the second side is greater than or equal to 4 micrometers and smaller than or equal to 6 micrometers in a plan view.

2. The display device of claim 1, wherein an inner side surface of the first insulating layer, which defines the opening, is slanted.

3. The display device of claim 2, wherein an angle between a lower surface of the first insulating layer and the inner side surface is greater than or equal to 65° and smaller than or equal to 80°.

4. The display device of claim 1, wherein the first insulating layer has a thickness that is equal to the distance between the first side and the second side.

5. The display device of claim 1, wherein an area of the opening is greater than an area of the light emitting opening in the plan view.

6. The display device of claim 1, wherein the display panel further comprises an encapsulation layer covering the light emitting element.

7. The display device of claim 6, wherein the encapsulation layer comprises:
a first inorganic layer on the light emitting element;
an organic layer on the first inorganic layer; and
a second inorganic layer on the organic layer.

8. The display device of claim 7, wherein the organic layer has a thickness greater than or equal to 2 micrometers and smaller than or equal to micrometers.

9. The display device of claim 1, further comprising an input sensing layer between the display panel and the first insulating layer, wherein the input sensing layer comprises:
a first conductive layer on the display panel;
a touch insulating layer on the first conductive layer; and
a second conductive layer on the touch insulating layer, and the first conductive layer and the second conductive layer do not overlap with the opening in the plan view.

10. The display device of claim 9, wherein the first insulating layer covers the second conductive layer.

11. The display device of claim 1, wherein the first refractive index is greater than or equal to 1.3 and smaller than or equal to 1.6, and the second refractive index is greater than or equal to 1.6 and smaller than or equal to 1.9.

12. The display device of claim 1, wherein the pixel definition layer comprises a black pigment or a black dye.

13. A display device comprising:
a display panel;
an organic pattern on the display panel and having a first refractive index; and
an insulating layer on the organic pattern and having a second refractive index different from the first refractive index, the display panel comprising:
a pixel definition layer through which a light emitting opening comprising a first side extending in a first direction is defined; and
a light emitting element in the light emitting opening, wherein the organic pattern comprises a second side extending in the first direction and defining the organic pattern in a plan view, and a distance between the first side and the second side is greater than or equal to 4 micrometers and smaller than or equal to 6 micrometers in the plan view.

14. The display device of claim 13, wherein the organic pattern overlaps with the light emitting opening in the plan view, and an area of the organic pattern is greater than an area of the light emitting opening in the plan view.

15. The display device of claim 13, wherein the first refractive index is greater than the second refractive index.

16. The display device of claim 15, wherein the first refractive index is greater than or equal to 1.6 and smaller than or equal to 1.9, and the second refractive index is greater than or equal to 1.3 and smaller than or equal to 1.6.

17. The display device of claim 13, wherein an inner side surface of the organic pattern, which defines the organic pattern, is slanted.

18. The display device of claim 17, wherein an angle between a lower surface of the organic pattern and the inner side surface is greater than or equal to 65° and smaller than or equal to 80°.

19. The display device of claim 13, wherein the organic pattern has a thickness that is equal to the distance between the first side and the second side.

20. An electronic device comprising:
a display panel configured to display an image;
a processor configured to provide image data to the display panel;
a first insulating layer on the display panel and having a first refractive index;
a second insulating layer on the first insulating layer and having a second refractive index different from the first refractive index; and
a window on the second insulating layer, the display panel comprising:
a pixel definition layer through which a light emitting opening comprising a first side extending in a first direction is defined; and
a light emitting element in the light emitting opening, wherein an opening comprising a second side extending in the first direction is defined through the first insulating layer to overlap with the light emitting opening, and a distance between the first side and the second side is greater than or equal to 4 micrometers and smaller than or equal to 6 micrometers in a plan view.
